(19) United States
(12) Patent Application Publication
(10) Pub. No.: US 2009/0134496 A1
(43) Pub. Date: May 28, 2009

(54) WAFER AND METHOD OF FORMING ALIGNMENT MARKERS

(75) Inventors: Scott Warrick, Crolles (FR); Clyde Browning, Grenoble (FR); Kevin Cooper, Weatherford, GA (US); Cindy Goldberg, Montbonnot (FR); Brad Smith, Gieres (FR)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 12/305,109

(22) PCT Filed: Jul. 6, 2006
(86) PCT No.: PCT/IB2006/054091

§ 371 Date: Dec. 16, 2008

(51) Int. Cl. H01L 23/544; H01L 21/76

(52) U.S. Cl. 257/620; 257/797; 438/401; 257/E23.179; 257/E21.54

(57) ABSTRACT

A wafer comprises a multi-layer structure. The multi-layer structure includes a first device structure neighbouring an area for receiving alignment markers. A plurality of alignment markers extend into the multi-layer structure and are located within the area for receiving alignment markers. The plurality of alignment markers is arranged to prevent propagation of a crack, when occurring, beyond a material-dependent critical length in a part of the multi-layer structure corresponding to the area for receiving the alignment structure. The material-dependent critical length is associated with the part of the multi-layer structure.

### FIELD OF THE INVENTION

This invention relates to a multi-layer structure of the type, for example, comprising a first device structure neighbouring an area for receiving alignment markers. This invention also relates to a method of forming alignment markers in a multi-layer structure of the type used, for example, to align a wafer.

### BACKGROUND OF THE INVENTION

In the field of semiconductor device fabrication, it is known to form a number of identical semiconductor devices on a semiconductor wafer. Once formed, the devices then need to be separated into individual piece-parts for subsequent processing, including packaging. Die separation, dicing, or cleaving is a processing step by which the semiconductor wafer is cut into so-called “chips” thereby liberating the semiconductor devices from each other. The semiconductor devices can be integrated circuits, or other structures also having precise dimensions, such as sensors, Micro-ElectroMechanical Systems (MEMS) or liquid crystal panel structures.

It is known, when processing the semiconductor wafer to form multi-layer structures, to form markers in the multi-layer structures. The markers formed can be recognised by an optical system during processing of the semiconductor wafer to align the wafer with, for example, a projection system for patterning the wafer using a mask.

In order to dice the wafer into individual devices a so-called “scribe-lane” or “scribe-line” is provided on the wafer between dice, for example between a first semiconductor device and a second semiconductor device. The width of the scribe lane is greater than a cutting edge of a dicing tool used to dice the semiconductor wafer. The scribe lane is bordered by edge seals either side of the scribe lane to protect each die bordered by the scribe lanes from diffusion of moisture, contamination and from penetration of dicing-generated chipping into the die.

Typically, the alignment markers are disposed in the scribe lane for aligning the wafer with the mask and are formed as groups of lines formed from, for example, metal or polysilicon that can lie both on and beneath an uppermost surface of the wafer. Consequently, when the semiconductor wafer is diced, the cutting edge of the dicing tool usually cuts across the alignment markers, which are continuous elongate formations in the multi-layer structure. As cutting occurs, it is known for cracking and “delamination” to take place either side of a cut made by the cutting tool. Such cracking and/or delamination extends into neighbouring dice, resulting in damage to devices formed adjacent the cut and hence a reduction in device yield from a given semiconductor wafer.

One known solution is to widen the scribe lane, thereby creating a greater distance between devices and sites of potential cracking and delamination when the wafer is diced. However, such a solution results in a reduction in available space on the wafer for circuits, resulting in less revenue from the wafer.

### STATEMENT OF INVENTION

According to the present invention, there is provided a multi-layer structure and a method of forming alignment markers as set forth in the appended claims.

### BRIEF DESCRIPTION OF THE DRAWINGS

At least one embodiment of the invention will now be described, by way of example only, with reference to the accompanying drawings, in which:

FIG. 1 is a schematic plan view of alignment markers disposed upon a surface of a multi-layer structure and constituting an embodiment of the invention;

FIG. 2 is a schematic diagram of a first part of a patterning stage for formation of the alignment markers of FIG. 1;

FIG. 3 is a schematic diagram of a second part of a patterning stage for formation of the alignment markers of FIG. 1;

FIG. 4 is a schematic diagram of a trench formation stage for formation of the alignment markers of FIG. 1;

FIG. 5 is a schematic diagram of a metal deposition stage for formation of the alignment markers of FIG. 1;

FIG. 6 is a schematic diagram of a planarisation stage for formation of the alignment markers of FIG. 1; and

FIG. 7 is a schematic plan view of the part of an alignment marker of alignment markers of FIG. 1.

### DESCRIPTION OF PREFERRED EMBODIMENTS

Throughout the following description identical reference numerals will be used to identify like parts.

The example described herein is generally applicable to multi-layer structures that are susceptible to cracking, particularly as a result of the presence of metallisation layers, such as copper metallisation layers.

In order to fabricate a number of semiconductor devices, a semiconductor substrate has a number of different layers of materials formed thereon, thereby constituting a multi-layer structure. Each layer of the multi-layer structure has a distinct pattern, depending upon the semiconductor devices being formed. The distinct pattern of each layer of the multi-layer structure is achieved using any suitable patterning technique known in the art.

Typically, latter stages of semiconductor device fabrication, sometimes referred to as the “back end” of the processing, are metallisation stages where electrical contacts between layers of the multi-layer structure are interconnected to interconnect parts of each semiconductor device being formed to complete the structure of each semiconductor device. In this respect, it is known to form so-called “integrations” as part of the metallisation processes.

The foregoing example of formation of alignment markers will be described in the context of one known type of integration, namely the Trench-First with metal Hard Mask integration described in “Alignment robustness for 90 nm and 65 nm node through copper alignment mark integration optimization” (S. Warrick et al., Proceedings of SPIE, Volume 5754 Optical Microlithography XVIII, May 2004, pp. 854-864). However, the skilled person will appreciate that the formation of alignment markers described herein can be applied to other metallisation stages employing other integrations, or indeed other layers of the multi-layer structure not provided exclusively or even partially to support metallisation.

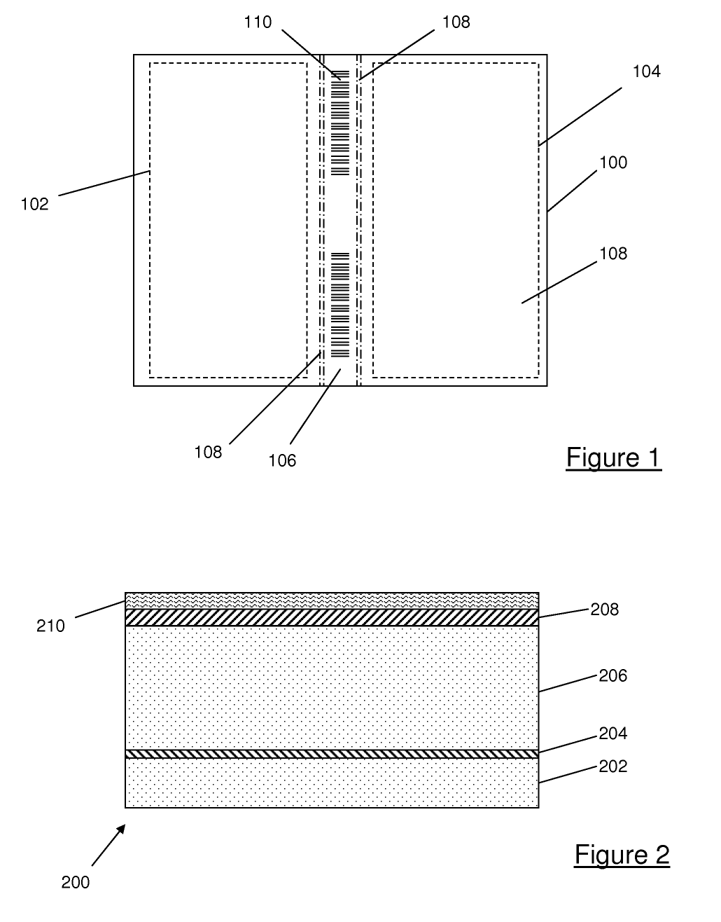

Referring to FIG. 1, a wafer comprising a multi-layer structure 100 includes a plurality of device formations, for example, a first device formation 102 located in the multi-layer structure 100 adjacent a second device formation 104 in the multi-layer structure 100. The device formations are separated from each other by scribe lanes 106 bordered by adjacent edge seals 108. In this example, the first and second device formations, 102, 104 are semiconductor devices.

Metallisation integration (not shown in FIG. 1) is formed on upper layers of the multi-layer structure 100 in order to provide interconnect lines. In this example, the metal employed is copper, though the skilled person will appreciate that other metals can be employed for other multi-layer structures. As part of the formation of the metallisation integration, alignment markers 110 are formed in a manner described later herein.

Turning to FIG. 2, the integration 200 comprises a first low-k dielectric layer 202. Although not shown in FIG. 2, metal lines are embedded in the first low-k layer 202. However, the alignment markers 110 to be formed, are formed away from other metal features such as the metal lines mentioned above, in the scribe lane 106.

A silicon carbon nitride (SiCN) etch stop and passivation layer 204 is disposed adjacent the first low-k layer 202, a second low-k layer 206 being disposed adjacent the SiCN layer 204.

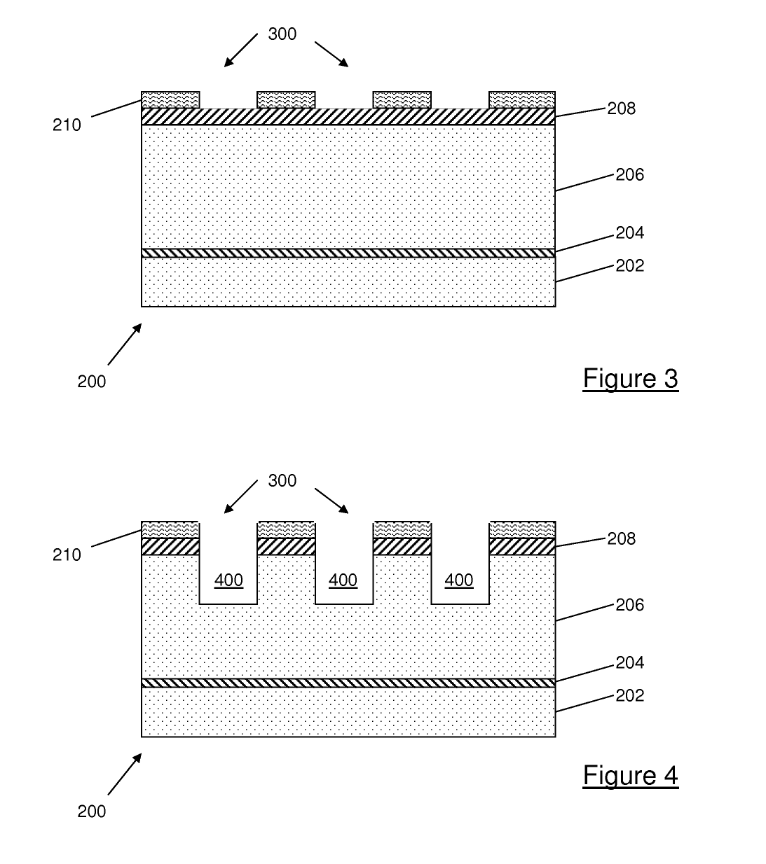

A silicon dioxide (SiO₂) layer 208 is disposed adjacent the second low-k layer 206 and a metal hard mask layer 210 is disposed upon the silicon dioxide layer 208. Turning to FIG. 3, a pattern (not shown) to form trenches is etched into the metal hard mask layer 210 using conventional photolithographic and etch techniques.

In addition to patterns used to form trenches in the above-described arrangement, the photolithography mask also comprises patterns 300 for the formation of the alignment markers 110 at the same time as the formation of the trenches. In this respect, the mask is used to project a repeating pattern of discrete elements, the elements being spaced apart. In this example, the pattern is a longitudinally extending array of squares. In this example, the array is four elements wide by 18 elements long, and repeats, in groups of three, in a direction perpendicular to the longitudinal extension of the array.

Of course, the number of elements in the array and indeed the dimensions and/or shape of the array can vary depending upon the optical alignment system to be used with the multi-layer structure 100. In this example, the size of each element is 200 nm×200 nm at a pitch of 400 nm. However, the skilled person will appreciate that the shape of the elements, the size of the elements and/or inter-element spacings can also vary. For example, the shape of each element need not be exactly square and can be rounded or rectangular. The width of a given element can be between about 80 nm and about 300 nm. However, the spacing between adjacent elements of the array is sufficiently small to enable the optical alignment system to treat each array of elements as continuous, for example less than about 300 nm.

The repeating nature of the array serves as a diffraction grating to diffract an alignment beam of electromagnetic radiation incident upon the array of elements, i.e. the diffraction grating. The process of alignment using the alignment marker is simply an application of the alignment marker described herein and so will not be described further. However, the skilled person will recognise that the pitch between adjacent elements is sufficiently small to prevent appreciable incoherent scattering of any orders of diffracted electromagnetic radiation. Consequently, in this example, the spacing between individual elements is less than the wavelength of light used by the optical alignment system, such as less than 633 nm and/or 532 nm.

Referring to FIG. 4, the pattern in the hard mask is transferred into the silicon dioxide layer 208 and the second low-k layer 206 using a Reactive Ion Etching (RIE) technique, resulting in an array of trenches 400 being formed.

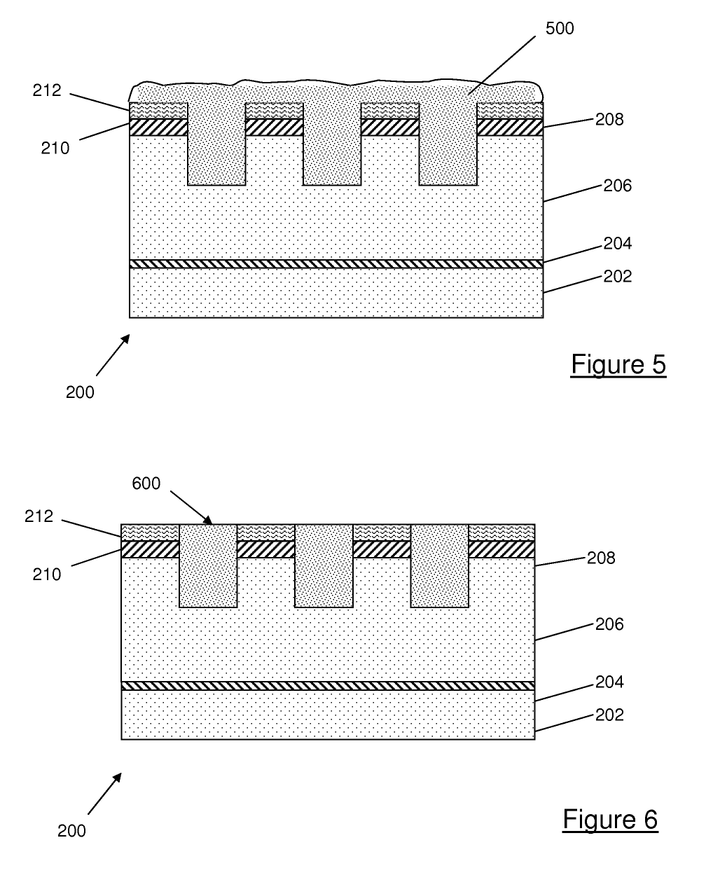

The trenches 400 are then coated with a metal barrier layer and a seed layer (both not shown) using a sputtering technique. Thereafter, the trenches 400 are filled with metal 500 (FIG. 5), for example copper, using an electroplating technique.

The metallisation integration 200 is then subjected to a polish step using, in this example, a Chemical Mechanical Polish (CMP) technique until an uneven surface of the metallisation integration 200 has been planarised to leave a substantially flat exposed surface 600 (FIG. 6).

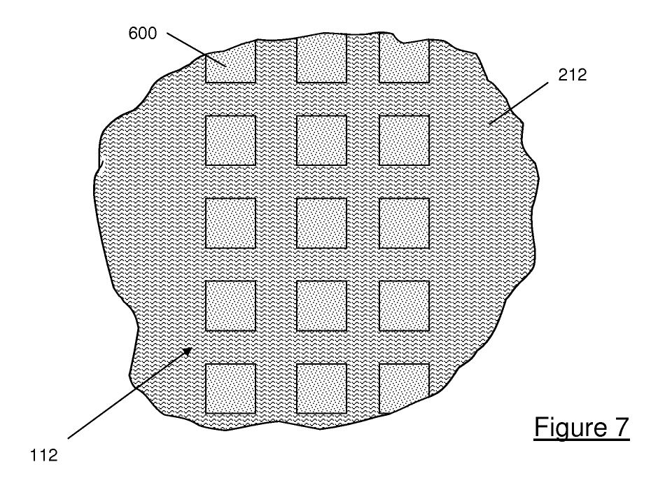

Referring to FIG. 7, after completion of the CMP stage, the array of elements, constituting one of the alignment markers 112, remains on the surface 600 of the metallisation integration 200.

The formation of the alignment markers described above serves to provide a greater degree of variation of geometric structure and materials in a part of the multi-layer structure 100 that corresponds to the scribe lane, i.e. in a path of a potential crack, as compared with known alignment markers. In this respect, variation of material and/or geometric structure in the multi-layer structure 100 beneath the scribe lane is provided in three dimensions.

In this example, a saw tool is used as part of a dicing process to separate or liberate individual device formations of the wafer from each other, each individual device formation constituting, in this example, an individual die. The saw tool is a DFD 6360 made by Disco Corporation of Japan, operating at a spindle speed of 45000 rpm±25% in the presence of deionised water having a resistivity of 1.5 MΩm. However, the resistivity can be between about 1.4 and about 1.8 MΩm. The wafer is processed at a feed rate of 50 mms±20% using an NBC-ZH 2050 27 HEEE blade also made by Disco Corporation.

When the saw tool is urged against the substantially flat surface 600 in the scribe lane 106, a so-called “crack tip opening” is formed in the surface 600 as a result of the load applied by the dicing tool exceeding a threshold load value dictated by the materials from which the multi-layer structure 100 is composed. Thereafter, with continued application of force to the surface 600, a crack forms and propagates until a critical crack length of the crack is reached. Again, the critical crack length is dictated by the materials from which the multi-layer structure 100 is composed. If unimpeded, and the crack exceeds the critical length, the crack becomes unstable and propagates at a greater rate and in an unpredictable matter.

However, the variation of material and geometric structure provided by the alignment markers in the path of the crack serves to limit propagation of the crack substantially to the inter-element spacing adjacent the crack, thereby preventing the crack reaching the critical length described above. Consequently, the crack does not propagate significantly outside the periphery of the alignment markers.

Reduced crack formation and/or delamination in the scribe lane therefore results to an extent that such damage does not extend beyond the scribe lane, i.e. leave the scribe lane, and impinge upon the first and/or second device formation 102, 104 as a result of dicing the wafer or the introduction of any other fracture in the scribe lane. The alignment markers also serve to reduce cracking caused by thermo-mechanical stresses induced during fabrication of the multi-layer structure 100.

After sawing, the wafer is, in this example, washed for 60 s (±about 50%) at 1200 rpm (±about 10%), then rinsed for 10 s (±about 50%) at 800 rpm (±about 100%) and then dried for 40 s (±about 50%) at 1500 rpm (±about 10%).

Although the above example has been described in the context of the scribe lane, the skilled person will appreciate that the above technique applies equally to any area that can receive alignment markers.

It is thus possible to provide a multi-layer structure and a method of forming alignment markers that, whilst taking advantage of existing processing steps to form device structures, provide alignment markers that do not cause cracking or delamination of the multi-layer structure, especially for low-k, Ultra-low k (ULK), and air-gap integration schemes. However, the alignment markers still appear continuous to the optical system of a wafer alignment system. Depending upon the back end integration technique employed, defectively caused by contaminants in large trenches is mitigated. Further, distortion of alignment marks caused by use of the CMP technique, sometimes known as “dishing”, is mitigated. Of course, the above advantages are exemplary, and these or other advantages may be achieved by the invention. Further, the skilled person will appreciate that not all advantages stated above are necessarily achieved by embodiments described herein.

1. A wafer comprising:
a multi-layer structure including a first device structure neighbouring an area for receiving alignment markers;
a plurality of alignment markers extending into the multi-layer structure and located within the area for receiving alignment markers, the plurality of alignment markers being usable to align the wafer; characterised in that:
the plurality of alignment markers also prevent propagation of a crack, when occurring, beyond a material-dependent critical length in a part of the multi-layer structure corresponding to the area for receiving the alignment markers, the material-dependent critical length being associated with the part of the multi-layer structure.

2. A wafer as claimed in claim 1, wherein the plurality of alignment markers is arranged to provide a variation of material in three dimensions in the part of the multi-layer structure so as to prevent the crack propagating beyond the material-dependent critical length.

3. A wafer as claimed in claim 1 wherein the plurality of alignment markers is arranged to provide a variation of geometric structure in three dimensions in the part of the multi-layer structure so as to prevent the crack propagating beyond the material-dependent critical length.

4. A wafer as claimed in claim 2, wherein the variation of material is discrete.

5. A wafer as claimed in claim 3, wherein the variation of geometric structure is discrete.

6. A wafer as claimed in claim 1, wherein each of the plurality of alignment markers comprises a plurality of elements arranged to define the each of the plurality of alignment markers.

7. A wafer as claimed in claim 6, wherein the crack does not propagate substantially beyond an inter-element spacing of the plurality of alignment markers.

8. A wafer as claimed in claim 6, wherein the plurality of elements is arranged as an array of elements.

9. A wafer as claimed in claim 6, wherein repeats of the plurality of elements are separated in a first direction by a first pitch, the first pitch being sufficiently small to diffract, when in use, electromagnetic radiation incident thereupon, at least one order of the diffracted electromagnetic radiation being capable of use for maintaining accuracy of an alignment apparatus when aligning a mask with the wafer.

10. A wafer as claimed in claim 9, wherein the repeats of the plurality of elements are separated in a second direction substantially perpendicular to the first direction by a second pitch, the second pitch being sufficiently small to diffract, when in use, the electromagnetic radiation incident thereupon, at least one order of the diffracted electromagnetic radiation being capable of use for maintaining accuracy of the alignment apparatus when aligning the mask with the wafer.

11. A wafer as claimed in claim 1, wherein the plurality of alignment markers is a plurality of elongate markings.

12. A wafer as claimed in claim 6, wherein the plurality of elements is arranged to form an elongate pattern.

13. A wafer as claimed in claim 2, wherein the elongate pattern is substantially rectangular.

14. A wafer as claimed in claim 1, wherein each of the plurality of alignment markers is a diffraction grating.

15. A wafer as claimed in claim 1, wherein the first device structure is a first semiconductor device.

16. A wafer as claimed in claim 1, wherein the area for receiving alignment markers is a scribe lane.

17. A wafer as claimed in claim 1, further comprising a second device structure spaced from the first device structure by the area for receiving alignment markers.

18. A wafer as claimed in claim 7, wherein the second device structure is a second semiconductor device.

19. Dice formed by separation from each other and originating from the wafer as claimed in claim 1.

20. A method of forming alignment markers in a multi-layer structure that includes a first device structure neighbouring an area for receiving alignment markers, the method comprising the steps of:
forming a plurality of alignment markers in the multi-layer structure and located within the area for receiving alignment markers, the plurality of alignment markers being usable to align a wafer;
forming the plurality of alignment markers so as also to prevent propagation of a crack, when occurring, beyond a material-dependent critical length in a part of the multi-layer structure corresponding to the area for receiving the alignment markers, the material-dependent critical length being associated with the multi-layer structure.

21. A method as claimed in claim 20, further comprising the steps of:
forming vias in the multilayer structure; and
forming the plurality of alignment markers substantially contemporaneously with the formation of the vias.

22. (canceled)
